(19) United States
(12) Patent Application Publication
(10) Pub. No.: US 2002/0185307 A1
(43) Pub. Date: Dec. 12, 2002

(54) Printed circuit board

(75) Inventors: Axel Gurel, Grafelfing (DE); Andreas Huber, Maisach (DE); Peter Niedermeier, Munchen (DE); Bernhard Reiter, Munchen (DE); Alwin Veser, Hallbergmoos (DE)

Correspondence Address: YOUNG & THOMPSON, 745 SOUTH 23RD STREET 2ND FLOOR, ARLINGTON, VA, 22202

(73) Assignee: Patent-Treuhand-Gesellschaft Fur elektrische Gluhlampen mgH, Munchen (DE)

(21) Appl. No.: 10/119,845

(22) Filed: Apr. 11, 2002

(30) Foreign Application Priority Data
Jun. 6, 2001 (DE) 10127334.7

(51) Int. Cl. H05K 1/16

(52) U.S. Cl. 174/260

(57) ABSTRACT

The present invention relates to a printed circuit board for soldering and/or loading electronic components on one or both sides, the individual components having at least one electrically conducting contact element for insertion into at least one corresponding contact opening (12) penetrating through the printed circuit board (10), the contact opening (12) of the printed circuit board (10) being of a slit-shaped form.

### TECHNICAL FIELD

The invention relates to a printed circuit board according to the precharacterizing clause of claim 1. It concerns in particular a printed circuit board for soldering and/or loading electronic components on one or both sides, the individual components having at least one electrically conducting contact element for insertion into at least one corresponding contact opening penetrating through the printed circuit board.

### BACKGROUND ART

Printed circuit boards of this type are known. To allow printed circuit boards of this type to be connected to electronic components, known printed circuit boards have round holes penetrating through the printed circuit board, which are usually plated-through. Appropriate contact elements or contact pins of the electronic components to be connected to the printed circuit board are inserted into these openings. These contact elements are subsequently soldered to the plated-through holes of the printed circuit board or to corresponding conductor tracks of the printed circuit board.

However, a disadvantage of these known printed circuit boards is that, when the described conventional holes are used for the mounting of standard electronic components, a low construction is not possible, since these components cannot be inserted deep enough into the printed circuit board on account of the widening of the contact elements or contact pins toward the component. To achieve an overall depth that is as low as possible, until now expensive special components, such as surface mounted devices (SMDs) for example, have been used.

### DISCLOSURE OF THE INVENTION

It is an object of the present invention to provide a printed circuit board according to the precharacterizing clause of claim 1 which, when loaded with standard electronic components, ensures an overall depth that is as low as possible.

This object is achieved in the case of a printed circuit board with the features of the precharacterizing clause of claim 1 by the features of the characterizing clause of claim 1. Especially advantageous configurations can be found in the dependent claims.

A printed circuit board according to the invention has at least one contact opening for inserting electrically conducting contact elements of electronic components which is of a slit-shaped form. This configuration of the contact opening of the printed circuit board makes it possible for the contact elements or contact pins of the components to be inserted completely or virtually completely into the printed circuit board, so that the housing of the electronic components rests on the printed circuit board or comes to lie at a very small distance from it. As a result, altogether a very low overall height of the entire element comprising the printed circuit board and the electronic component attached on it is ensured.

In an advantageous configuration of the invention, the slit-shaped contact opening is metallized for the plated-through contact. This is of advantage in particular in the case of double-sided printed circuit boards, since it is consequently possible for printed circuit boards to be loaded with components on one side and said components to be connected to the conductor tracks of the printed circuit board on the opposite side of the board.

In a further advantageous configuration of the printed circuit board according to the invention, the slit-shaped contact opening has at least one slit-shaped transverse opening running perpendicularly in relation to the longitudinal axis of the contact opening. It is also possible, however, for the slit-shaped transverse opening to run obliquely in relation to the longitudinal axis of the contact opening. The transverse milled openings serve for isolating the individual conductor tracks for the respective contact elements or contact pins of the components. The isolation spacing between the individual contact elements is at a maximum when there is a corresponding width of the slit-shaped transverse opening, in addition to which the leakage paths are advantageously increased by the slit-shaped transverse openings. Furthermore, it is advantageously possible by suitable choice of the slit lengths of the contact opening and/or of the transverse opening to ensure an automatic centering of the components to be inserted.

In a further advantageous configuration of the invention, the contact opening and the transverse opening can be formed by means of drilling, milling or punching.

### BRIEF DESCRIPTION OF THE DRAWINGS

The invention is to be explained in more detail below on the basis of several exemplary embodiments. In the drawings:

FIG. 1 shows a schematic representation of a printed circuit board according to the invention; and

FIG. 2 shows a schematic representation of a printed circuit board according to the invention in a further exemplary embodiment.

### BEST MODE FOR CARRYING OUT THE INVENTION

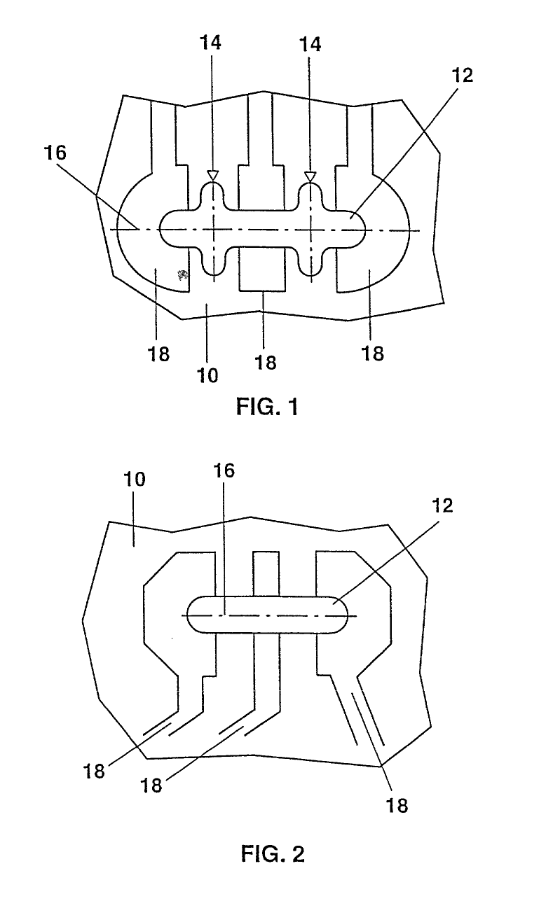

FIG. 1 shows in a schematic representation a printed circuit board 10 with metallized conductor tracks 18. The exemplary embodiment shown concerns a double-sided printed circuit board. From the side of the printed circuit board 10 that is not represented, contact elements, in particular contact pins, of individual components, in particular electronic components, are inserted into a contact opening 12 of the printed circuit board 10. It can be seen that the contact opening 12 is of a slit-shaped form, slit-shaped transverse openings 14 likewise being formed approximately perpendicularly in relation to a longitudinal axis 16 of the contact opening 12. The transverse openings 14 in this case run approximately parallel to the conductor tracks 18 and protrude beyond both longitudinal sides of the contact opening 12. By contrast with the slit-shaped contact opening 12, the transverse openings 14 are not metallized and serve for the isolation of the individual conductor tracks 18 and the corresponding contact elements of the electronic component from one another.

The slit-shaped contact opening 12 and the slit-shaped transverse openings 14 can be produced by drilling, milling or punching.

FIG. 2 shows in a schematic representation a further exemplary embodiment of a printed circuit board 10. This exemplary embodiment concerns a single-sided printed circuit board 10, which likewise has a slit-shaped contact opening 12 with a corresponding longitudinal axis 16. It can be seen that the slit-shaped contact opening 12 connects three conductor tracks 18 to one another. In the case of the single-sided printed circuit board 10 represented, the slit-shaped contact opening is not metallized. This is only necessary in the case of double-sided printed circuit boards according to the exemplary embodiment in FIG. 1 for the plated-through contact.

The special configuration of the contact openings 12 according to the exemplary embodiments in FIGS. 1 and 2 makes it possible for standard components which are to be attached on the printed circuit boards 10 to be inserted deeper than in the case of conventional printed circuit boards, so that lower overall heights can be realized.

1. A printed circuit board for soldering and/or loading electronic components on one or both sides, the individual components having at least one electrically conducting contact element for insertion into at least one corresponding contact opening (12) penetrating through the printed circuit board (10), characterized in that the contact opening (12) of the printed circuit board (10) is of a slit-shaped form.

2. The printed circuit board as claimed in claim 1, characterized in that the slit-shaped contact opening (12) is metallized for the plated-through contact.

3. The printed circuit board as claimed in claim 1 or 2, characterized in that the slit-shaped contact opening (12) has at least one slit-shaped transverse opening (14) running perpendicularly in relation to the longitudinal axis (16) of the contact opening (12).

4. The printed circuit board as claimed in claim 1 or 2, characterized in that the slit-shaped contact opening (12) has at least one slit-shaped transverse opening running obliquely in relation to the longitudinal axis (16) of the contact opening (12).

5. The printed circuit board as claimed in one of the preceding claims, characterized in that the transverse opening (14) protrudes beyond both longitudinal sides of the contact opening (12).

6. The printed circuit board as claimed in one of the preceding claims, characterized in that the transverse opening (14) is formed for the isolation of two contact elements of an electronic component and the associated conductor tracks (18) of the printed circuit board (10).

7. The printed circuit board as claimed in one of the preceding claims, characterized in that the contact opening and the transverse opening can be formed by means of drilling, milling or punching.
